(19) United States
(12) Patent Application Publication
(10) Pub. No.: US 2024/0376599 A1
(43) Pub. Date: Nov. 14, 2024

(54) SILICON PRECURSOR COMPOUND, COMPOSITION FOR FORMING SILICON-CONTAINING FILM COMPRISING SAME, AND METHOD FOR FORMING FILM USING COMPOSITION FOR FORMING SILICON-CONTAINING FILM

(71) Applicant: UP CHEMICAL CO., LTD., Pyeongtaek-si, Gyeonggi-do (KR)

(72) Inventors: Byung Kwan KIM, Pyeongtaek-si (KR); Jin SiK KIM, Pyeongtaek-si (KR); Da Som YU, Pyeongtaek-si (KR)

(73) Assignee: UP CHEMICAL CO., LTD., Pyeongtaek-si, Gyeonggi-do (KR)

(21) Appl. No.: 18/577,885

(22) PCT Filed: Jul. 13, 2022
(86) PCT No.: PCT/KR2022/010198

§ 371 Date: Jan. 9, 2024

(30) Foreign Application Priority Data
Jul. 16, 2021 (KR) 10-2021-0093732
Jul. 23, 2021 (KR) 10-2021-0097389

(51) Int. Cl. C23C 16/455; C01B 33/12; C07F 7/10; C23C 16/40; H01L 21/02

(52) U.S. Cl. CPC C23C 16/45527; C01B 33/126; C07F 7/10; C23C 16/402; H01L 21/02164; H01L 21/02208

(57) ABSTRACT

A silicon precursor compound, a composition for forming a silicon-containing film, wherein the composition contains the compound; and a method for forming a silicon-containing film by using the composition for forming a silicon-containing film are disclosed. The composition for forming a silicon-containing film includes a silicon precursor compound having a specific structure, thus making it possible to achieve the self-limiting film growth of ALD over a wide temperature range of 150° C. to 850° C., control the thickness of the silicon-containing film to be extremely thin and uniform, and form a film having excellent coverage and uniformity even on a substrate having a complex shape, and furthermore, further improve the characteristics of a semiconductor device.

### TECHNICAL FIELD

The present invention relates to a silicon precursor compound, a composition for forming a silicon-containing film comprising the same, and a method for forming a film using the composition for forming a silicon-containing film.

### BACKGROUND ART

In recent years, a technology of applying a dielectric film, which reduces leakage current by doping a small amount of silicon (Si) to a high-k dielectric material such as a zirconium oxide film (ZrO₂), to a semiconductor device is being actively studied. In such an event, when the dielectric film contains excessive silicon, the dielectric constant decreases; thus, it is necessary to adjust the silicon content of the silicon-containing film to a low level.

In this regard, for the purpose of application to a dielectric film of DRAM, a method has been disclosed in which an atomic layer deposition (ALD) cycle to form a zirconium oxide film (ZrO₂) and an ALD cycle to form a silicon-containing oxide film (SiO₂) are combined to form a silicon-containing film, the silicon content of which is 1 to 4% by atom (Patent Document 1).

In addition, a semiconductor device has also been disclosed in which a dielectric film stack whose leakage current is reduced by applying a SiO₂ film having a thickness of 0.1 to 0.2 nm is used (Patent Document 2).

Although these patent documents disclose techniques for controlling the silicon content or controlling the thickness of a SiO₂ film, the growth per cycle of gas supply in the SiO₂ film can only be controlled in a unit of 0.6 Å/cycle or more; thus, there is still a limit to more precisely controlling the thickness of the SiO₂ film.

Meanwhile, products having a complex shape such as a high aspect ratio and a three-dimensional structure are variously developed in the memory field and non-memory field. Therefore, there is a demand for developing a composition for forming a thin film that comprises a silicon precursor compound that has self-limiting film growth characteristics at a high temperature of 600° C. or higher, as well as at a low temperature of lower than 600° C., and is capable of achieving a uniform and very thin silicon-containing film; and for developing a method for forming a silicon-containing film using the same.

### PRIOR ART DOCUMENTS

### Patent Documents

(Patent Document 1) U.S. Patent Application Publication No. 2010/0035439
(Patent Document 2) U.S. Patent Application Publication No. 2020/0020780
(Patent Document 3) Korean Patent No. 10-0734393

### DISCLOSURE OF INVENTION

### Technical Problem

An object of the present invention is to provide a composition for forming a silicon-containing film, which comprises a silicon precursor compound having self-limiting film growth characteristics in a broad temperature range of a high temperature of 600° C. or higher, as well as a low temperature of lower than 600° C.

Another object of the present invention is to provide a novel silicon precursor compound contained in a composition for forming a silicon-containing film capable of achieving the above characteristics and a method for preparing the same.

However, the problems to be solved by the present application are not limited to those mentioned above, and other problems not mentioned will be clearly understood by those skilled in the art from the following description.

### Solution to Problem

The present invention provides a composition for forming a silicon-containing film, which comprises a silicon precursor compound represented by the following Formula 1:

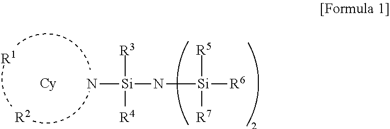

In Formula 1,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O), nitrogen (N), and carbon (C), and
R³ to R⁷ are each independently selected from the group consisting of hydrogen, a linear or branched C₁-C₄ alkyl group, and a linear or branched C₂-C₆ alkenyl group, provided that at least one of R³ and R⁴ is not hydrogen; and that at least one of R⁵ to R⁷ is not hydrogen.

In addition, the present invention provides a method for forming a silicon-containing film, which comprises depositing a silicon-containing film using a composition for forming a silicon-containing film comprising a silicon precursor compound represented by Formula 1.

In addition, the present invention provides a silicon-containing film formed using a composition for forming a silicon-containing film comprising a silicon precursor compound represented by Formula 1.

Further, the present invention provides a method for preparing a silicon precursor compound, which comprises subjecting an alkyldisilazane metal salt represented by the following Formula A to a halide-amine substitution reaction with triethylamine, a dihalide silicon precursor compound represented by the following Formula B, and a heterocyclic amine or a heterocyclic amine metal salt represented by the following Formula C:

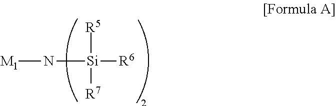

In Formula A,
M₁ is an alkali metal and Li or Na, and
R⁵ to R⁷ are each independently selected from the group consisting of hydrogen, a linear or branched C₁-C₄ alkyl group, and a linear or branched C₂-C₆ alkenyl group, provided that at least one of R⁵ to R⁷ is not hydrogen,

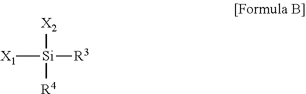

in Formula B,
X₁ and X₂ are each independently a halogen element and Cl, Br, or I, and
R³ and R⁴ are each independently selected from the group consisting of hydrogen, a linear or branched C₁-C₄ alkyl group, and a linear or branched C₂-C₆ alkenyl group, provided that at least one of R³ and R⁴ is not hydrogen, and

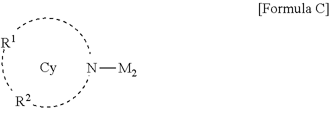

in Formula C,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O), nitrogen (N), and carbon (C), and
M₂ is selected from the group consisting of hydrogen, Li, and Na.

### Advantageous Effects of Invention

As the composition for forming a silicon-containing film according to an embodiment of the present invention comprises a silicon precursor compound having a specific structure, it has self-limiting film growth characteristics in a broad temperature range of a high temperature of 600° C. or higher, as well as a low temperature of lower than 600° C. In particular, it is possible to control the thickness of a silicon-containing film to be very thin and uniform by atomic layer deposition (ALD). The silicon-containing film thus formed and having a thin and uniform thickness can be advantageously applied to a dielectric film stack or the like.

In addition, an ALD cycle for forming a silicon-containing film using the composition for forming a silicon-containing film and an ALD cycle for forming a film containing another metal may be combined to form a silicon-containing composite film containing silicon and another metal. In such an event, the silicon content of the silicon-containing composite film may be finely adjusted within a low range.

### BRIEF DESCRIPTION OF DRAWINGS

FIG. 1 is a graph showing the results of thermogravimetric analysis (TGA) measurement of the silicon compounds in Examples 1 to 3 of the present invention.

FIG. 2 is a graph showing the deposition characteristics of a silicon-containing oxide film with respect to a temperature of 150° C. to 450° C. when the silicon-containing film is deposited by ALD using a composition for forming a silicon-containing film comprising each of the silicon precursor compounds of Examples 1 and 3 and Comparative Examples 1 and 2 of the present invention.

FIG. 3 is a graph showing the deposition characteristics of a silicon-containing oxide film with respect to a temperature of 600° C. to 850° C. when the silicon-containing film is deposited by ALD using a composition for forming a silicon-containing film comprising each of the silicon precursor compounds of Examples 1, 2, 3, 4, 5, and 8 and Comparative Example 1 of the present invention.

FIG. 4 is a graph showing the results of secondary ion mass spectrometry (SIMS) of a silicon-containing oxide film deposited at a temperature of 750° C. using a composition for forming a silicon-containing film comprising each of the silicon precursor compounds of Examples 1 and 3 and Comparative Example 1 of the present invention.

FIG. 5 is a transmission electron microscope (TEM) image confirming the step coverage by depositing on a patterned wafer at 750° C. using a composition for depositing a silicon-containing film comprising each of the silicon precursor compound of Examples 1 and 3 and Comparative Example 1 of the present invention.

### BEST MODE FOR CARRYING OUT THE INVENTION

Hereinafter, the present invention will be described in detail.

In addition, in the present specification, in the case where an element is mentioned to be formed “on” another element, it means not only that one element is directly formed “on” another element, but also that other element(s) is interposed between them.

In the present specification, when a part is referred to as “comprising” an element, it is to be understood that the part may comprise other elements as well, rather than exclude other elements, unless otherwise indicated.

All numbers and expressions related to the quantities of components, reaction conditions, and the like used herein are to be understood as being modified by the term “about,” unless otherwise indicated.

In the present specification, each of the terms “film” and “thin film” refers to both “film” and “thin film,” unless otherwise specified.

In the present specification, the term “alkyl” or “alkyl group” covers linear or branched alkyl groups and all possible isomers thereof. For example, the alkyl or alkyl group covers not only a methyl group (Me), an ethyl group (Et), a normal propyl group (ⁿPr), an isopropyl group (ⁱPr), a normal butyl group (ⁿBu), an isobutyl group (ⁱBu), a tert-butyl group (tert-Bu, ^{t}Bu), sec-butyl group (^{sec}Bu), and the like, but also isomers thereof, and the like, but it is not limited thereto.

In the present specification, unless otherwise stated, a “solid line” symbol in a chemical formula indicates a direct connection between atoms, and a “dotted line” symbol indicates an indirect connection between atoms, as well as a direct connection between atoms.

### Composition for Forming a Silicon-Containing Film

An embodiment of the present invention provides a composition for forming a silicon-containing film, which comprises a silicon precursor compound represented by the following Formula 1:

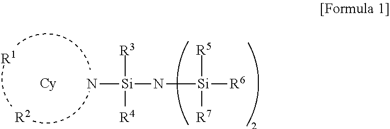

In Formula 1,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O)), nitrogen (N), and carbon (C), and
R³ to R⁷ are each independently selected from the group consisting of hydrogen, a linear or branched C₁-C₄ alkyl group, and a linear or branched C₂-C₆ alkenyl group, provided that at least one of R³ and R⁴ is not hydrogen; and that at least one of R⁵ to R⁷ is not hydrogen.

Here, Cy may comprise a ring in which N, R¹, and R² are directly connected to each other or a ring in which N, R¹, and R² are indirectly connected to each other via another atom. Specifically, in the case where Cy comprises a ring in which N, R¹, and R² are indirectly connected to each other via another atom, for example, it may comprise a ring in which they are indirectly linked to each other via a carbon atom, such as N—C—R¹—R², N—C—C—R¹—R², and N—C—C—R¹—C—R².

As the composition for forming a silicon-containing film according to an embodiment of the present invention comprises a silicon precursor compound represented by Formula 1, it is possible to control the thickness of a silicon-containing film to be very thin and uniform by atomic layer deposition (ALD), as well as chemical vapor deposition (CVD), and to control the thickness of a silicon-containing film to be very thin and uniform in a broad temperature range of, for example, 150° C. to 850° C.

Specifically, the composition for forming a silicon-containing film, which comprises the silicon precursor compound having the above specific structure, has a small growth per cycle (GPC) of ALD gas supply at a low temperature of lower than 600° C.; thus, it is possible to form an extremely thin silicon-containing film by ALD.

For example, when a conventionally known composition for forming a silicon-containing film is used, the SiO₂ film growth per cycle (GPC) of ALD gas supply formed by ALD at a deposition temperature of 150° C. to 450° C. exceeds 0.05 nm (GPC>0.05 nm/cycle). On the other hand, when the composition for forming a silicon-containing film of the present invention is used, the SiO₂ film growth per cycle (GPC) of ALD gas supply is 0.5 nm or less (GPC≤0.05 nm/cycle), for example, about 0.1 to 0.2 nm/cycle; thus, it is advantageous for forming a SiO₂ film having an extremely thin thickness. It also has a huge advantage in that it is possible to achieve a silicon-containing thin film having an extremely thin thickness with an excellent step coverage in a high aspect ratio process, for example, in a process such as a DRAM capacitor that requires fine thickness control.

In addition, when an ALD cycle for forming a silicon-containing film using the composition for forming a silicon-containing film and an ALD cycle for forming a film containing another metal are combined to form a silicon-containing composite film containing silicon and another metal, it is possible to finely control the silicon content of the silicon-containing composite film.

Specifically, for the purpose of combining an ALD gas supply cycle for forming a film of high-k dielectricity such as HfO₂ and ZrO₂ with an ALD gas supply cycle for forming SiO₂ film to form a composite film containing a small amount of Si in a film of high-k dielectric material, a low SiO₂ GPC may be advantageous. For example, when the silicon content of the silicon-containing composite film is adjusted to 1 to 4% by atom, its step may be finely controlled.

In addition, since the silicon precursor compound is highly volatile, is present in a liquid state at room temperature, and can provide a silicon-containing film of high quality in various ways, it can be advantageous in terms of product variety, excellent quality, and manufacturing process.

As the silicon precursor compound contained in the composition for forming a silicon-containing film according to an embodiment of the present invention has a structure in which various types of amines and alkyl groups are bonded to Si, it is very advantageous for forming a stable and dense film even at high temperatures, as well as low temperatures. It is possible to form a stable silicon-containing film in various temperature range of 150° C. or higher, 200° C. or higher, 250° C. or higher, and 850° C. or lower, or 800° C. or lower, for example, 150° C. to 850° C., 150° C. to 800° C., 150° C. to 750° C., 150° C. to 700° C., 150° C. to 600° C., 150° C. to 500° C., 150° C. to 450° C., 200° C. to 450° C., 250° C. to 450° C., 250° C. to 400° C., higher than 400° C. to lower than 600° C., 500° C. to 850° C., 600° C. to 850° C., or 650° C. to 800° C.

That is, in the silicon precursor compound represented by Formula 1, first, the amine contained in the ring (Cy) in which N, R¹, and R² are directly or indirectly connected to each other in the above structure has excellent surface reactivity, which is advantageous for forming a silicon-containing oxide film; second, as at least one of R³ and R⁴ in the moiety represented by R³—Si—R⁴ in the above structure is not hydrogen, that is, at least one of R³ and R⁴ has an alkyl group or an alkenyl group, preferably, at least one of R³ and R⁴ has an alkyl group, the thermally stable bonding of Si and C makes it possible to form a stable film without rapidly decomposing the silicon precursor at high temperatures, so that it may be suitable for a three-dimensional NAND flash memory process that requires characteristics of a silicon-containing film at high temperatures; and third, the structure contains three Si elements and has a significantly larger GPC in SiO₂ ALD than that of the conventionally known silicon precursor compound, so that it may be suitable for a three-dimensional NAND flash memory process in which a thick SiO₂ film is to be formed at high temperature.

Further, since the silicon precursor compound is excellent in thermal stability as it is present in a liquid state at room temperature. In particular, it is advantageous for forming silicon-containing films such as silicon-containing oxide films, silicon-containing nitride films, silicon-containing carbide films, and silicon-containing composite metal films by ALD.

Specifically, in Formula 1, Cy may comprise a substituted or unsubstituted pyrrolidine group, a substituted or unsubstituted piperidine group, a substituted or unsubstituted piperazine group, or a substituted or unsubstituted morpholine group. Specifically, Cy may comprise a pyrrolidine group, a piperidine group, a 2-methylpiperidine group, a piperazine group, a 1-methylpiperazine group, or a morpholine group.

R¹ and R² are each independently selected from the group consisting of oxygen (O), nitrogen (N), and carbon (C). For example, R¹ and R² may each independently be carbon (C). In addition, R¹ and R² may each independently be selected from the group consisting of carbon (C) and oxygen (O). In addition, R¹ and R² may each independently be selected from the group consisting of carbon (C) and nitrogen (N).

In addition, in Formula 1, R³ and R⁴ may each independently be selected from the group consisting of hydrogen, a methyl group, an ethyl group, an n-propyl group, an iso-propyl group, an n-butyl group, and an iso-butyl group.

For example, —SiR³R⁴ may be selected from the group consisting of —SiHMe₂, —SiHEt, —SiH(ⁿPr), —SiH(ⁱPr), —SiH(ⁿBu), —SiMe₂, —SiEt₂, —Si(ⁿPr)₂, —Si(ⁱPr)₂, and —Si(ⁿBu)₂.

In addition, in Formula 1, R⁵ to R⁷ may each independently be selected from the group consisting of hydrogen, a methyl group, an ethyl group, an n-propyl group, and an iso-propyl group.

For example, —SiR⁵R⁶R⁷ may be selected from the group consisting of —SiHMe₂, —SiH₂Me, —SiHMeEt, —SiHMe(ⁿPr), —SiHMe(ⁱPr), —SiHEt₂, —SiHEt(ⁿPr), —SiHEt(ⁱPr), —SiH(ⁿPr)₂, —SiH(ⁿPr)(ⁱPr), —SiH(ⁱPr)₂, —SiMe₃, —SiEt₃, and —Si(ⁿPr)₃.

Here, “Me” refers to a methyl group, “Et” refers to an ethyl group, “ⁿPr” refers to a normal propyl group, “ⁱPr” refers to an isopropyl group, and “Bu” refers to a normal butyl group.

For example, the silicon precursor compound may comprise at least one selected from the group consisting of compounds represented by the following Formulae 1-1 to 1-16:

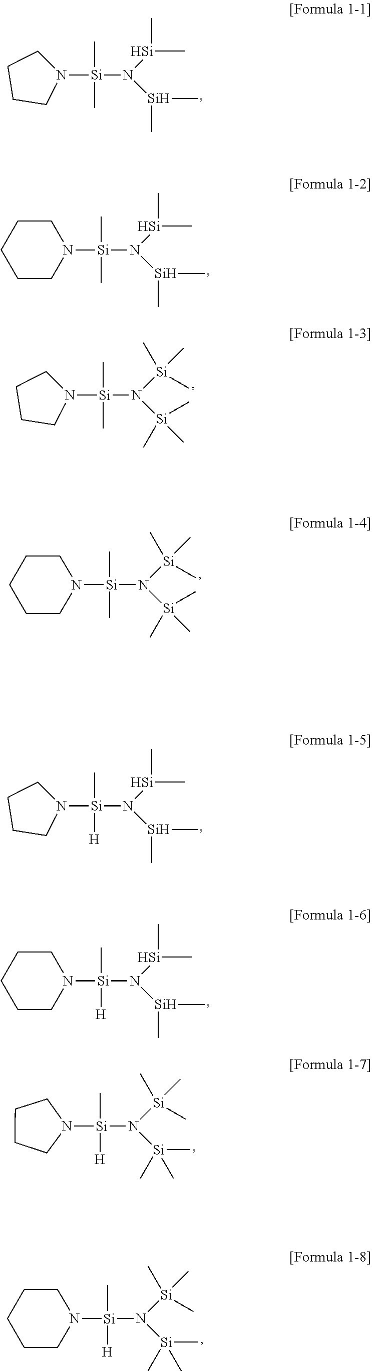

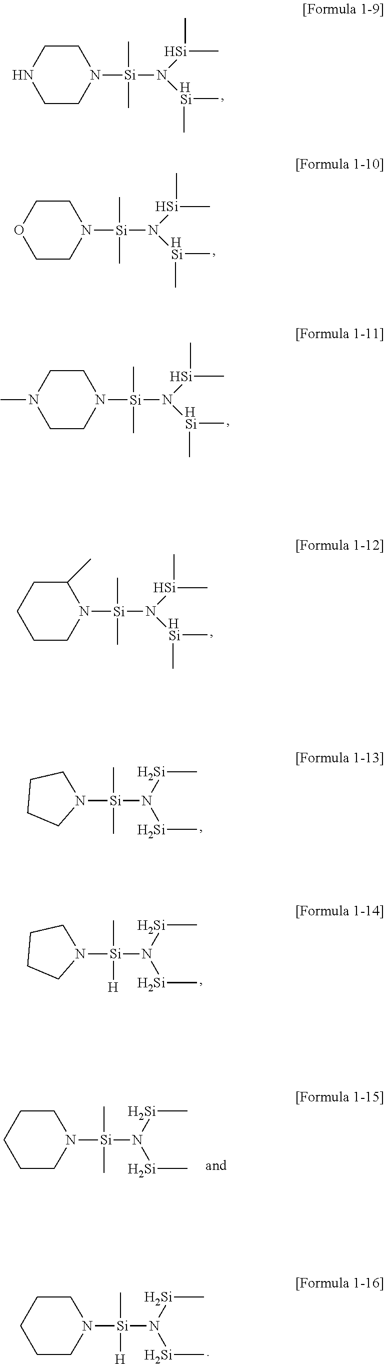

According to an embodiment of the present invention, when a SiO₂ film is formed by ALD using the composition for forming a silicon-containing film, it may have a growth per cycle (GPC) of ALD gas supply of 0.08 to 4.5 Å/cycle in a temperature range of 150° C. to 850° C.

Specifically, when a SiO₂ film is formed by ALD using the composition for forming a silicon-containing film, it is possible to achieve various growth per cycle (GPC) values of ALD gas supply in various temperature ranges.

For example, when a SiO₂ film is formed by ALD using the composition for forming a silicon-containing film, it is possible to achieve a growth per cycle (GPC) of ALD gas supply of 0.08 to 0.35 Å/cycle, for example, 0.1 to 0.35 Å/cycle, or, for example, 0.1 to 0.25 Å/cycle in a temperature range of 150° C. to 400° C., specifically, 250° C. to 400° C. or 250° C. to 350° C. In particular, when a SiO₂ film is formed by ALD using the composition for forming a silicon-containing film, the growth per cycle (GPC) of ALD gas supply may be, for example, 0.1 to 0.35 Å/cycle, for example, 0.1 to 0.3 Å/cycle, for example, 0.1 to 0.25 Å/cycle, or, for example, 0.1 to 0.2 Å/cycle at about 300° C.

If the growth per cycle (GPC) of ALD gas supply at 150° C. to 400° C., specifically, 250° C. to 400° C. or 250° C. to 350° C., for example, 300° C. satisfies the above ranges when a SiO₂ film is formed by ALD using the composition for forming a silicon-containing film, it is possible to form a thin silicon-containing film; thus, it may be more advantageous for forming an extremely thin film used for a dielectric film of a semiconductor device. For example, when a SiO₂ film is formed by ALD using the composition for forming a silicon-containing film, it may be advantageous for forming a SiO₂ film having a thickness of about 0.5 nm or less, for example, 0.1 to 0.2 nm by ALD.

In addition, when a SiO₂ film is formed by ALD using the composition for forming a silicon-containing film, it is possible to achieve a growth per cycle (GPC) value of ALD gas supply of, for example, 0.20 to 2.5 Å/cycle in a temperature range of higher than 400° C. to lower than 600° C.

Specifically, when a SiO₂ film is formed by ALD using the composition for forming a silicon-containing film, it is possible to achieve a growth per cycle (GPC) value of ALD gas supply of, for example, 0.2 to 2.3 Å/cycle, 0.2 to 2.0 Å/cycle, 0.22 to 2.0 Å/cycle, 0.22 to 1.8 Å/cycle, 0.22 to 1.5 Å/cycle, 0.24 to 1.0 Å/cycle, 0.24 to 0.8 Å/cycle, or 0.24 to 0.5 Å/cycle in a temperature range of higher than 400° C. to lower than 600° C. or higher than 400° C. to 500° C.

In addition, when a SiO₂ film is formed by ALD using the composition for forming a silicon-containing film, it is possible to achieve a growth per cycle (GPC) value of ALD gas supply of, for example, 1.5 to 4.5 Å/cycle in a temperature range of 600° C. to 850° C.

Specifically, when a SiO₂ film is formed by ALD using the composition for forming a silicon-containing film, it is possible to achieve a growth per cycle (GPC) value of ALD gas supply of 1.5 to 3.5 Å/cycle, 1.7 to 3.0 Å/cycle, or 1.75 to 2.5 Å/cycle in a temperature range of 600° C. to 850° C. In addition, when a SiO₂ film is formed by ALD using the composition for forming a silicon-containing film, it is possible to achieve a growth per cycle (GPC) value of ALD gas supply of 1.5 to 2.5 Å/cycle, 1.7 to 2.5 Å/cycle, or 1.75 to 2 Å/cycle in a temperature range of 600° C. to 800° C. In addition, when a SiO₂ film is formed by ALD using the composition for forming a silicon-containing film, it is possible to achieve a growth per cycle (GPC) value of ALD gas supply of 1.5 to 2.5 Å/cycle, 1.7 to 2.5 Å/cycle, 1.75 to 2.5 Å/cycle, 1.75 to 2.49 Å/cycle, 1.75 to 2.4 Å/cycle, or 1.75 to 2.0 Å/cycle in a temperature range of 600° C. to 750° C.

If a silicon-containing film is formed using the composition for forming a silicon-containing film according to an embodiment of the present invention, it is possible to control the composition to achieve a desired film thickness and a desired silicon content and to form a film having excellent coverage and uniform thickness even on a substrate having patterns (grooves) on its surface, a porous substrate, a plastic substrate, or a substrate having a complex shape of a three-dimensional structure, whereby it is possible to provide a silicon-containing film of high quality.

### Method for Preparing a Silicon Precursor Compound

Meanwhile, the silicon precursor compound represented by Formula 1 may be prepared by various methods.

The method for preparing a silicon precursor compound according to an embodiment of the present invention comprises subjecting an alkyldisilazane metal salt represented by the following Formula A to a halide-amine substitution reaction with triethylamine, a dihalide silicon precursor compound represented by the following Formula B, and a heterocyclic amine or a heterocyclic amine metal salt represented by the following Formula C:

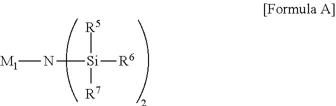

In Formula A,
M₁ is an alkali metal and Li or Na, and
R⁵ to R⁷ are each independently selected from the group consisting of hydrogen, a linear or branched C₁-C₄ alkyl group, and a linear or branched C₂-C₆ alkenyl group, provided that at least one of R⁵ to R⁷ is not hydrogen,

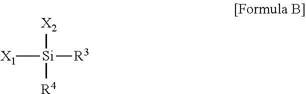

in Formula B,
X₁ and X₂ are each independently a halogen element and Cl, Br, or I, and
R³ and R⁴ are each independently selected from the group consisting of hydrogen, a linear or branched C₁-C₄ alkyl group, and a linear or branched C₂-C₆ alkenyl group, provided that at least one of R³ and R⁴ is not hydrogen, and

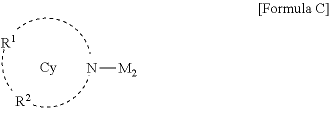

in Formula C,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O), nitrogen (N), and carbon (C), and
M₂ is selected from the group consisting of hydrogen, Li, and Na.

Specifically, as can be seen from the following Reaction Scheme 1, an alkyldisilazane metal salt represented by the following Formula A, triethylamine (TEA), a dihalide silicon precursor compound represented by the following Formula B, and a heterocyclic amine or a heterocyclic amine metal salt represented by the following Formula C are subjected to a selective amine ligand substitution in a non-polar solvent, followed by purification thereof, to obtain a compound of Formula 1.

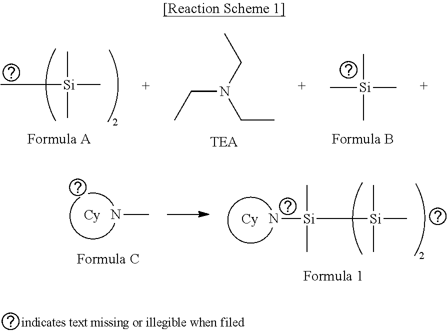

In Reaction Scheme 1, Cy, R¹ to R⁷, M₁, M₂, X₁, and X₂ are as defined above.

Referring to Reaction Scheme 1 above, 1 to 3 moles of triethylamine and 0.5 to 2 moles of a dihalide silicon precursor compound (Formula B) are added to an alkyldisilazane metal salt (Formula A) at a low temperature to carry out a substitution reaction of halide and amine at room temperature, 0.5 to 2 moles of a heterocyclic amine or a heterocyclic amine metal salt (Formula C) is added thereto at a low temperature to carry out a substitution reaction of halide and amine at room temperature, the reaction by-products in the form of a metal halide salt or a triethylamine halide salt are removed through a filter, and the resultant is purified to obtain the silicon precursor compound represented by Formula 1.

The halide-amine substitution reaction may be carried out in a solvent at −5° C. to −30° C.

In addition, the solvent may comprise one or more selected from the group consisting of an alkane having 5 to 8 carbon atoms, toluene, ether, tetrahydrofuran, and mono- to tetra-ethylene glycol dimethyl ether.

For example, for a silicon precursor compound represented by Formula 1-1, as can be seen from the following Reaction Scheme 2, lithium (1,1,3,3-tetramethyldisilazane) salt is reacted with triethylamine and dichlorodimethylsilane at a low temperature of about −10° C. to −30° C., for example, about −10° C. to −20° C., for about 5 to 30 hours for a substitution reaction of Cl and amine, and pyrrolidine is reacted at a low temperature of about-10° C. to −30° C., for example, about −10° C. to −20° C. for about 5 to 30 hours for a substitution reaction of Cl and amine to obtain the compound of Formula 1-1.

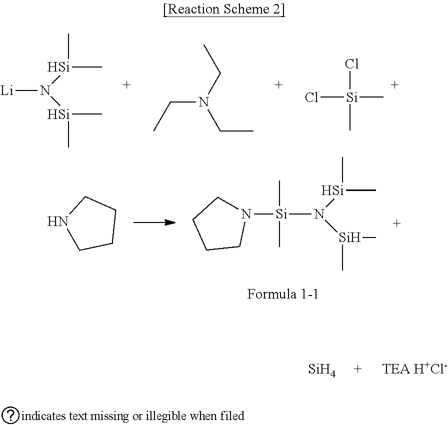

In Reaction Scheme 2, the lithium (1,1,3,3-tetramethyldisilazane) salt may be prepared by reacting normal butyl lithium (n-BuLi) and 1,1,3,3-tetramethyldisilazane in hexane as a non-polar solvent at low temperatures.

In Reaction Scheme 2, in order to safely remove salts (LiCl, TEA·HCl) as reaction products and unreacted dichlorodimethylsilane and to suppress decomposition reactions caused by moisture or oxygen during the reaction, it is preferable to carry out the reaction under a flow of nitrogen (N₂) or argon (Ar).

According to an embodiment of the present invention, the silicon precursor compound may be used to obtain a composition for forming a silicon-containing film comprising the silicon precursor compound.

### Method for Forming a Silicon-Containing Film

According to an embodiment of the present invention, there may be provided a method for forming a silicon-containing film, which comprises depositing a silicon-containing film using a composition for forming a silicon-containing film comprising the silicon precursor compound represented by Formula 1.

Specifically, the method for forming a silicon-containing film comprises depositing a silicon-containing film using a composition for forming a silicon-containing film comprising the silicon precursor compound represented by Formula 1 on a substrate by CVD or ALD.

According to the method for forming a silicon-containing film according to an embodiment of the present invention, as a composition for forming a silicon-containing film comprising the silicon precursor compound having a specific structure represented by Formula 1 is used, it is possible to form a film having excellent coverage and uniform thickness even on a substrate having a complex shape.

Specifically, a composition for forming a silicon-containing film comprising the silicon precursor compound represented by Formula 1 may be supplied in a gaseous state to a reaction chamber to form at least one selected from the group consisting of a silicon-containing oxide film, a silicon-containing nitride film, a silicon-containing carbide film, and a silicon-containing composite metal film on the substrate by CVD or ALD.

The substrate may be a silicon semiconductor wafer, a compound semiconductor wafer, and a plastic substrate (PI, PET, or PES), but it is not limited thereto. In addition, a substrate having holes or grooves may be used, and a porous substrate having a large surface area may be used.

In particular, it is possible to uniformly form a silicon-containing film having a thickness of several nanometers (nm) to several micrometers (μm) even on a substrate having patterns (grooves) on its surface, a porous substrate, or a plastic substrate in a temperature range of 150° C. to 850° C. It is possible to produce an excellent effect of forming a silicon-containing film having a uniform thickness on a substrate, covering the deepest surface of fine patterns (grooves) and the upper surface of the fine irregularities (grooves) having an aspect ratio of 1 or more, for example, about 1 to 50 or more and a width of 1 μm or less, for example, about 1 μm to 10 nm or less.

The deposition method of a silicon-containing film may use any methods and apparatuses known in the art to which the present invention pertains; if necessary, it may be carried out using one or more additional reactant gases or the like.

The deposition method of a silicon-containing film may be carried out by CVD, for example, organometallic chemical vapor deposition (MOCVD), or ALD. The MOCVD or ALD may be carried out using a deposition apparatus, deposition conditions, and reactive gases known in the art.

Specifically, a substrate is accommodated in a reaction chamber, a composition for forming a silicon-containing film comprising the silicon precursor compound is then transferred onto the substrate using a transport gas or a diluent gas, and a silicon-containing film is deposited at a deposition temperature of 150° C. to 850° C., for example, a low temperature of 150° C. to 450° C. or 150° C. to 400° C., a medium temperature of higher than 400° C. to lower than 600° C., or a high temperature of 600° C. to 850° C.

Here, the deposition temperature of 150° C. to 850° C. allows it to be applied to memory devices, logic devices, and display devices. Since the process temperature is broad, it can be applied to various fields. In particular, as the composition for forming a silicon-containing film comprising the silicon precursor compound that is resistant to stress and capable of forming a dense film at a high temperature of 600° C. to 850° C. is used, deposition is readily carried out in the above deposition temperature range.

In addition, it is preferable to use at least one mixed gas selected from the group consisting of argon (Ar), nitrogen (N₂), helium (He), and hydrogen (H₂) as the transport gas or diluent gas.

In addition, the method of delivering the silicon precursor compound into the reaction chamber may be at least one method selected from the group consisting of a bubbling method in which the composition for forming a silicon-containing film comprising the silicon precursor compound is forcibly vaporized using a transport gas or a diluent gas; a liquid delivery system (LDS) method for supplying it in a liquid phase at room temperature to be vaporized through a vaporizer; a vapor flow control (VFC) method for directly supplying the precursor using its vapor pressure; and a bypass method for vaporization by heating.

For example, if the vapor pressure is high, a vapor flow control method may be used. If the vapor pressure is low, a bypass method of vaporization by heating the vessel or a method of bubbling using argon (Ar) or nitrogen (N₂) gas may be used to supply the composition for forming a silicon-containing film comprising the silicon precursor compound into the reaction chamber.

More specifically, the delivery method comprises a bubbling method or a bypass method, in which the bubbling method may be carried out using a transport gas or a diluent gas in a temperature range of room temperature to 150° C. and 0.1 Torr to 10 Torr, and the bypass method may be carried out using a vapor pressure of 0.1 Torr to 1.5 Torr in a temperature range of room temperature to 100° C. For example, the supply of the composition for forming a silicon-containing film comprising the silicon precursor compound into the reaction chamber may be carried out using a transport gas or a diluent gas in a temperature range of room temperature to 100° C. and 0.1 Torr to 10 Torr.

In addition, in order to vaporize the composition for forming a silicon-containing film comprising the silicon precursor compound, for example, argon (Ar) or nitrogen (N₂) gas may be used for transportation thereof, thermal energy or plasma may be used during deposition, or a bias may be applied onto the substrate.

Meanwhile, according to the method of forming a silicon-containing film, in order to deposit a silicon-containing oxide film or a silicon-containing composite metal oxide film, at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O₂), hydrogen peroxide (H₂O₂), and ozone (O₃) may be used during deposition.

The silicon-containing oxide film or the silicon-containing composite metal oxide film may comprise at least one selected from the group consisting of, for example, HfSiOₓ, ZrSiOₓ, TiSiOₓ, HfAlOₓ, ZrAlSiOₓ, TiAlSiOₓ, ZrHfSiOₓ, ZrHfAlSiOₓ, SiC, SiCO, and SiON, but it is not limited thereto. Here, x may be 1 to 3.

In addition, in order to deposit a silicon-containing nitride film or a silicon-containing composite metal nitride film, at least one selected from the group consisting of ammonia (NH₃), ammonia plasma (HN₃ plasma), hydrazine (N₂H₄), and nitrogen plasma (N₂ plasma) may be used during deposition.

The silicon-containing nitride film or the silicon-containing composite metal nitride film may comprise at least one selected from the group consisting of, for example, HfSiNₓ, ZrSiNₓ, TiSiNₓ, AlSiNₓ, HfAlSiNₓ, ZrAlSiNₓ, TiAlSiNₓ, HfZrAlSiNₓ, HfZrTiSiNₓ, TAlSiNₓ, SiCN, SiOCN, and SiBN, but it is not limited thereto. Here, x may be 1 to 3.

### [Silicon-Containing Film]

According to an embodiment of the present invention, there is provided a silicon-containing film formed using a composition for forming a silicon-containing film comprising the silicon precursor compound represented by Formula 1.

The silicon-containing film may have a thickness of several nanometers (nm) to several micrometers (μm) and may be variously applied depending on the application purposes. Specifically, the silicon-containing film may be formed in a thickness range of 1 nm to 500 nm.

The silicon-containing film may be formed on a substrate (board).

The substrate is as described above.

As the silicon-containing film according to an embodiment of the present invention is prepared by using a composition for forming a silicon-containing film comprising a silicon precursor compound having a specific structure, it is excellent in thermal stability, so that it produces an excellent effect of forming a silicon-containing film with a thin and uniform thickness at high temperatures, as well as low temperatures, by CVD or ALD.

The silicon-containing film may be at least one selected from the group consisting of a silicon-containing oxide film, a silicon-containing composite metal oxide film, a silicon-containing nitride film, and a silicon-containing composite metal nitride film. Specifically, the silicon-containing film may comprise at least one selected from the group consisting of a silicon-containing oxide film and a silicon-containing composite metal oxide film.

In addition, as the silicon-containing film is prepared by using a composition for forming a silicon-containing film comprising a silicon precursor compound having excellent thermal stability, the silicon-containing film is characterized in that it has a low shrinkage even at a high temperature of 150° C. to 850° C., particularly 600° C. to 850° C., and a low wet etch rate (Å/s).

Specifically, the silicon-containing film may have a shrinkage (S₇₅₀) of 5.0% or less as represented by the following Equation 1:

$$Shrinkage ( {S}_{750} , \% ) = \frac{A - B}{A} \times 100 \qquad [ Equation 1 ]$$

In Equation 1, A is the initial thickness (Å) of a silicon-containing film formed by ALD at 750° C., and B is the thickness (Å) of the silicon-containing film formed by ALD at 750° C. after it is left at 750° C. in an argon (Ar) atmosphere for 60 minutes.

The shrinkage (S₇₅₀) of the silicon-containing film as represented by Equation 1 may be, for example, 3.9% or less, 3.8% or less, 3.5% or less, 3.3% or less, 3.2% or less, 3.0% or less, 2.5% or less, 2.0% or less, 1.5% or less, or 1.0% or less.

If the silicon-containing film has a shrinkage (S₇₅₀) satisfying the above range, it may be advantageous for forming a uniform and dense silicon-containing film.

Meanwhile, when the silicon-containing film is formed by deposition at 750° C. to a thickness of about 500 Å, and when the thickness of the silicon-containing film is measured with an ellipsometer before and after the silicon-containing film is exposed to an etching solution of 1% dilute hydrofluoric acid, the wet etch rate (Å/s) of the silicon-containing film represented by the following Equation 2 may be 4.0 Å/s or less:

$$Wet etch rate ( Å / s ) = etch thickness change ( Δ E , Å ) / 30 s \qquad [ Equation 2 ]$$

The etch thickness change (ΔE) may be represented by the following Equation 2-1:

$$Etch thickness change ( Δ E , Å ) = {E}_{A} - {E}_{B} \qquad [ Equation 2 - 1 ]$$

In Equation 2-1, E_{A} is the initial thickness (Å) of a silicon-containing film formed by ALD at 750° C., and E_{B} is the thickness (Å) of the silicon-containing film formed by ALD at 750° C. after it is etched in a 1% dilute HF solution for 30 seconds.

In Equation 2, “s” means seconds.

The wet etch rate (Å/s) of the silicon-containing film as represented by Equation 2 may be, for example, 3.8 Å/s or less, 3.5 Å/s or less, 3.2 Å/s or less, 3.0 Å/s or less, 2.8 Å/s or less, 2.5 Å/s or less, 2.2 Å/s or less, 2.0 Å/s or less, 1.5 Å/s or less, 1.0 Å/s or less, 0.5 Å/s or less, 0.1 Å/s or less, 0.05 Å/s or less, or 0.03 Å/s or less. Specifically, the wet etch rate (Å/s) of the silicon-containing film as represented by Equation 2 may be 3.8 Å/s to 0.5 Å/s, 3.5 Å/s to 0.5 Å/s, 3.0 Å/s to 1.0 Å/s, 2.5 Å/s to 1.0 Å/s, or 2.1 Å/s to 1.0 Å/s.

If the silicon-containing film has a wet etch rate (Å/s) satisfying the above range, it may be advantageous for forming a uniform and dense silicon-containing film.

In addition, the silicon-containing film may be very excellent in step coverage.

Specifically, when a silicon-containing film is deposited on a substrate having a stepped hole pattern as shown in FIG. 5 and then analyzed using a transmission electron microscope (TEM), the silicon-containing film has a step coverage (%) of, for example, 80% or more, for example, 82% or more, for example, 85% or more, for example, 90% or more, for example, 92% or more, for example, 93% or more, for example, 95% or more, or, for example, 96% or more.

If the silicon-containing film has a step coverage (%) satisfying the above range, a high step ratio and fine thickness control are possible, so that it can be advantageously used to manufacture various semiconductor devices such as DRAM and 3D NAND flash memory.

### MODE FOR THE INVENTION

Hereinafter, the present invention will be described in detail with reference to examples. The following examples are only illustrative of the present invention, and the scope of the present invention is not limited thereto.

### <Example 1> Preparation of pyrrolidinyl-(tetramethyldisilyl)amino-dimethylsilane and a Composition for Forming a Silicone-Containing Film Comprising the Same: [(CH₂CH₂CH₂CH₂N)Si(CH₃)₂{N(SiHMe₂)₂}]

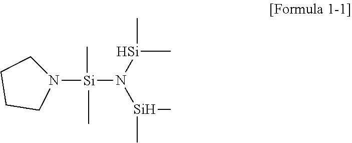

About 118.69 g (2.5 M, about 0.426 mole) of an n-butyllithium hexane solution (n-BuLi in n-hexane) was mixed with about 1,000 ml of anhydrous hexane in a 2-liter round bottom flask. About 61.99 g (about 0.4649 mole) of tetramethyldisilazane (1,1,3,3-tetramethyldisilazane) was added thereto at about −20° C., and the temperature was then gradually raised to room temperature under stirring, followed by stirring thereof for 4 hours. About 78.41 g (about 0.775 mole) of triethylamine was added to the lithium (1,1,3,3-tetramethyldisilazane) salt thus formed. About 50 g (about 0.387 mole) of dichlorodimethylsilane was slowly added thereto at −20° C. to −10° C., and the temperature was then gradually raised to room temperature under stirring, followed by stirring thereof for 4 hours. 4 hours later, about 33.06 g (about 0.465 mole) of pyrrolidine was added thereto at about −20° C., and the temperature was then gradually raised to room temperature under stirring, followed by stirring thereof for 17 hours. Upon completion of the reaction, the salt formed during the reaction was removed through filtration, and the solvent and volatile side reactants were removed under a reduced pressure to obtain 75 g (yield: 74.29%) of pyrrolidinyl-(tetramethyldisilyl)amino-dimethylsilane [(CH₂CH₂CH₂CH₂N)Si(CH₃)₂{N(SiHMe₂)₂}] as a colorless liquid compound represented by Formula 1-1, which was used for a composition for forming a film.

b.p.: 40° C. at 0.3 Torr (223.4° C. at 760 Torr)

1H-NMR(C₆D₆): δ 0.263 (Si—CH₃, s, 6H), δ 0.279, 0.271 (N—SiH—CH₃, d, 12H), δ 1.571 (N—CH₂—CH₂, m, 4H), δ 2.955 (N—CH₂—CH₂, m, 4H), δ 4.751 (N—Si—H, m, 2H)

### <Example 2> Preparation of piperidinyl-(tetramethyldisilyl)amino-dimethylsilane and a Composition for Forming a Silicone-Containing Film Comprising the Same: [(CH₂CH₂CH₂CH₂CH₂N)Si(CH₃)₂{N(SiHMe₂)₂}]

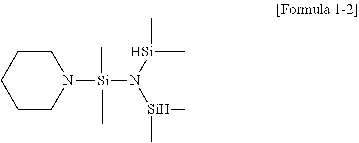

About 77.6 g (yield: about 73%) of piperidinyl-(tetramethyldisilyl)amino-dimethylsilane [(CH₂CH₂CH₂CH₂CH₂N)Si(CH₃)₂{N(SiHMe₂)₂}] as a colorless liquid compound represented by Formula 1-2 was obtained in the same manner as in Example 1, except that piperidine was used instead of pyrrolidine, and it was used for the composition for film formation.

b.p.: 50° C. at 0.3 Torr (237.5° C. at 760 Torr)

1H-NMR (C₆D₆): δ 0.240 (Si—CH₃, s, 6H), δ 0.269, 0.260 (N—Si—CH₃, d, 12H), δ 1.341 (N—CH₂—CH₂—CH₂, m, 4H), δ 1.488 (N—CH₂—CH₂—CH₂, m, 2H), δ 2.823 (N—CH₂—CH₂—CH₂, m, 4H), δ 4.747 (N—Si—H, m, 2H)

### <Example 3> Preparation of pyrrolidinyl-(hexamethyldisilyl)amino-dimethylsilane and a Composition for Forming a Silicone-Containing Film Comprising the Same: [(CH₂CH₂CH₂CH₂N)Si(CH₃)₂{N(SiMe₃)₂}]

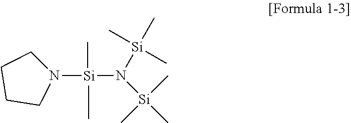

About 94.96 g (2.5 M, 0.341 mole) of an n-butyllithium hexane solution (n-BuLi in n-hexane) was mixed with about 500 ml of anhydrous hexane in a 2-liter round bottom flask. About 60.03 g (about 0.372 mole) of hexamethyldisilazane (1,1,1,3,3,3-hexamethyldisilazane) was added thereto at about-20° C., and the temperature was then gradually raised to room temperature under stirring, followed by stirring thereof for 4 hours. About 37.63 g (about 0.372 mole) of triethylamine was added to the lithium (1,1,1,3,3,3-hexamethyldisilazane) salt solution thus formed. About 50 g (about 0.387 mole) of dichlorodimethylsilane was slowly added thereto at about −20° C. to −10° C., and the temperature was then gradually raised to room temperature under stirring, followed by stirring thereof for 17 hours.

About 94.96 g (2.5 M, about 0.341 mole) of an n-butyllithium hexane solution (n-BuLi in n-hexane) was mixed with about 500 ml of anhydrous hexane in a 1-liter round bottom flask. About 26.45 g (about 0.372 mole) of pyrrolidine was added thereto at about −20° C., and the temperature was then gradually raised to room temperature under stirring, followed by stirring thereof for 4 hours. The lithium (pyrrolidine) salt solution thus formed was added to the 2-liter round bottom flask at about −20° C., and the temperature was then gradually raised to room temperature under stirring, followed by stirring thereof for 17 hours. Upon completion of the reaction, the salt formed during the reaction was removed through filtration, and the solvent and volatile side reactants were removed under a reduced pressure to obtain about 77.48 g (yield: about 69.29%) of pyrrolidinyl-(hexamethyldisilyl)amino-dimethylsilane [(CH₂CH₂CH₂CH₂N)Si(Me)₂{N(SiMe₃)₂}] as a colorless liquid compound represented by Formula 1-3, which was used for a composition for forming a film.

b.p.: 55° C. at 0.3 Torr (244.5° C. at 760 Torr)

1H-NMR (C₆D₆): δ 0.255 (Si—CH₃, s, 6H), δ 0.290 (N—Si—CH₃, s, 18H), δ 1.543 (N—CH—CH₂, m, 4H), δ 2.871 (N—CH₂—CH₂, m, 4H)

### <Example 4> Preparation of piperidinyl-(hexamethyldisilyl)amino-dimethylsilane and a Composition for Forming a Silicone-Containing Film Comprising the Same: [(CH₂CH₂CH₂CH₂CH₂N)Si(CH₃)₂{N(SiMe₃)₂}]

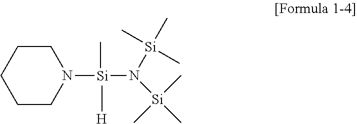

About 77.51 g (yield: about 66.1%) of piperidinyl-(hexamethyldisilyl)amino-dimethylsilane [(CH₂CH₂CH₂CH₂CH₂N)Si(CH₃)₂{N(SiMe₃)₂}] as a colorless liquid compound represented by Formula 1-4 was obtained in the same manner as in Example 3, except that piperidine was used instead of pyrrolidine, and it was used for the composition for film formation.

b.p.: 65° C. at 0.3 Torr (258.6° C. at 760 Torr)

1H-NMR (C₆D₆): δ 0.239 (Si—CH₃, s, 6H), δ 0.285 (N—Si—CH₃, s, 18H), δ 1.343 (N—CH₂—CH—CH₂, m, 4H), δ 1.491 (N—CH₂—CH—CH₂, m, 2H), δ 2.765 (N—CH—CH₂—CH₂, m, 4H)

### <Example 5> Preparation of pyrrolidinyl-(tetramethyldisilyl)amino-methylsilane and a Composition for Forming a Silicone-Containing Film Comprising the Same: [(CH₂CH₂CH₂CH₂N)SiH(CH₃){N(SiHMe₂)₂}]

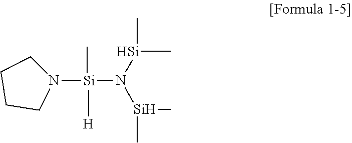

About 121.05 g (2.5 M, about 0.434 mole) of an n-butyllithium hexane solution (n-BuLi in n-hexane) was mixed with about 1,000 ml of anhydrous hexane in a 3-liter round bottom flask. About 57.95 g (about 0.434 mole) of tetramethyldisilazane (1,1,3,3-tetramethyldisilazane) was added thereto at about −20° C., and the temperature was then gradually raised to room temperature under stirring, followed by stirring thereof for 4 hours. 4 hours later, about 50 g (about 0.434 mole) of dichloromethylsilane was added thereto at about −20° C. to −10° C., and the temperature was then gradually raised to room temperature under stirring, followed by stirring thereof for 4 hours. 4 hours later, about 74.18 g (about 1.043 moles) of pyrrolidine was added thereto at about −20° C., and the temperature was then gradually raised to room temperature under stirring, followed by stirring thereof for 17 hours. Upon completion of the reaction, the salt formed during the reaction was removed through filtration, and the solvent and volatile side reactants were removed under a reduced pressure to obtain 82.52 g (yield: 77%) of pyrrolidinyl-(tetramethyldisilyl)amino-methylsilane [(CH₂CH₂CH₂CH₂N)SiH(CH₃){N(SiHMe₂)₂}] as a colorless liquid compound represented by Formula 1-5, which was used for a composition for forming a film.

b.p.: 30° C. at 0.3 Torr (209.3° C. at 760 Torr)

1H-NMR (C₆D₆): δ 0.309, 0.302 (Si—CH₃, d, 3H), δ 0.279, 0.274 (N—Si—CH₃, q, 12H), δ 1.547 (N—CH₂—CH₂, m, 4H), δ 2.963 (N—CH₂—CH₂, m, 4H), δ 4.786 (N—Si—H, m, 2H), δ 4.990 (Si—H, m, 1H)

### <Example 6> Preparation of piperidinyl-(tetramethyldisilyl)amino-methylsilane and a Composition for Forming a Silicone-Containing Film Comprising the Same: [(CH₂CH₂CH₂CH₂CH₂N)SiH(CH₃){N(SiHMe₂)₂}]

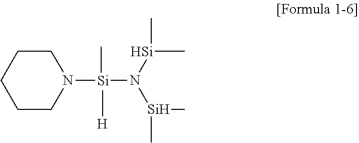

About 84.65 g (yield: about 74.71%) of piperidinyl-(tetramethyldisilyl)amino-methylsilane [(CH₂CH₂CH₂CH₂CH₂N)SiH(CH₃){N(SiHMe₂)₂}] as a colorless liquid compound represented by Formula 1-6 was obtained in the same manner as in Example 5, except that piperidine was used instead of pyrrolidine, and it was used for the composition for film formation.

b.p.: 40° C. at 0.3 Torr (223.4° C. at 760 Torr)

1H-NMR (C₆D₆): δ 0.290, 0.282 (Si—CH₃, d, 3H), δ 0.269, 0.261 (N—Si—CH₃, d, 12H), δ 1.362 (N—CH₂—CH₂—CH₂, m, 4H), δ 1.474 (N—CH₂—CH₂—CH₂, m, 2H), δ 2.860 (N—CH₂—CH₂—CH₂, m, 4H), δ 4.788 (N—Si—H, m, 2H), δ 4.893 (Si—H, m, 1H)

### <Example 7> Preparation of pyrrolidinyl-(hexamethyldisilyl)amino-methylsilane and a Composition for Forming a Silicone-Containing Film Comprising the Same: [(CH₂CH₂CH₂CH₂N)SiH(CH₃){N(SiMe₃)₂}]

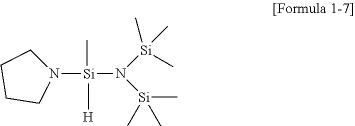

About 84.98 g (yield: about 71.19%) of pyrrolidinyl-(hexamethyldisilyl)amino-methylsilane [(CH₂CH₂CH₂CH₂N)SiH(CH₃){N(SiHMe₃)₂}] as a colorless liquid compound represented by Formula 1-7 was obtained in the same manner as in Example 5, except that hexamethyldisilazane (1,1,1,3,3,3-hexamethyldisilazane) was used instead of tetramethyldisilazane (1,1,3,3-tetramethyldisilazane), and it was used for the composition for film formation.

b.p.: 50° C. at 0.3 Torr (237.5° C. at 760 Torr)

¹H-NMR (C₆D₆): δ 0.298, 0.291 (Si—CH₃, d, 3H), δ 0.279 (N—Si—CH₃, s, 18H), δ 2.921 (N—CH₂—CH₂, m, 4H), δ 1.533 (N—CH₂—CH₂, m, 4H), δ 5.076 (Si—H, m, 1H)

### <Example 8> Preparation of piperidinyl-(hexamethyldisilyl)amino-methylsilane and a Composition for Forming a Silicone-Containing Film Comprising the Same: [(CH₂CH₂CH₂CH₂CH₂N)SiH(CH₃){N(SiMe₃)₂}]

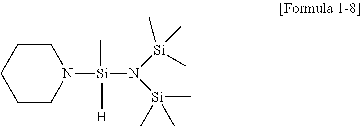

About 85.32 g (yield: about 68%) of piperidinyl-(hexamethyldisilyl)amino-methylsilane [(CH₂CH₂CH₂CH₂CH₂N)SiH(CH₃){N(SiMe₃)₂}] as a colorless liquid compound represented by Formula 1-8 was obtained in the same manner as in Example 5, except that piperidine was used instead of pyrrolidine and that hexamethyldisilazane (1,1,1,3,3,3-hexamethyldisilazane) was used instead of tetramethyldisilazane (1,1,3,3-tetramethyldisilazane), and it was used for the composition for film formation.

b.p.: 60° C. at 0.3 Torr (251.6° C. at 760 Torr)

1H-NMR (C₆D₆): δ 0.239, 0.232 (Si—CH₃, d, 3H), δ 0.268 (N—Si—CH₃, s, 18H), δ 1.364 (N—CH₂—CH₂—CH₂, m, 4H), δ 1.478 (N—CH₂—CH₂—CH₂, m, 2H), δ 2.819 (N—CH₂—CH₂—CH₂, m, 4H), δ 5.001 (Si—H, m, 1H)

### Comparative Example 1

Tris(dimethylamido) silane (3DMAS or TDMAS) [SiH(NMe₂)₃] (manufactured by UP Chemical Co., Ltd.) was used.

### Comparative Example 2

Tris(pyrrolidino) silane (TPYS) [SiH[N(CH₂)₄]₃ (manufactured by UP Chemical Co., Ltd.), in which a cyclic amine pyrrolidine is substituted instead of dimethylamine, was used.

### Test Example

### <Test Example 1> Analysis of the Thermal Characteristics of Silicon Precursor Compounds

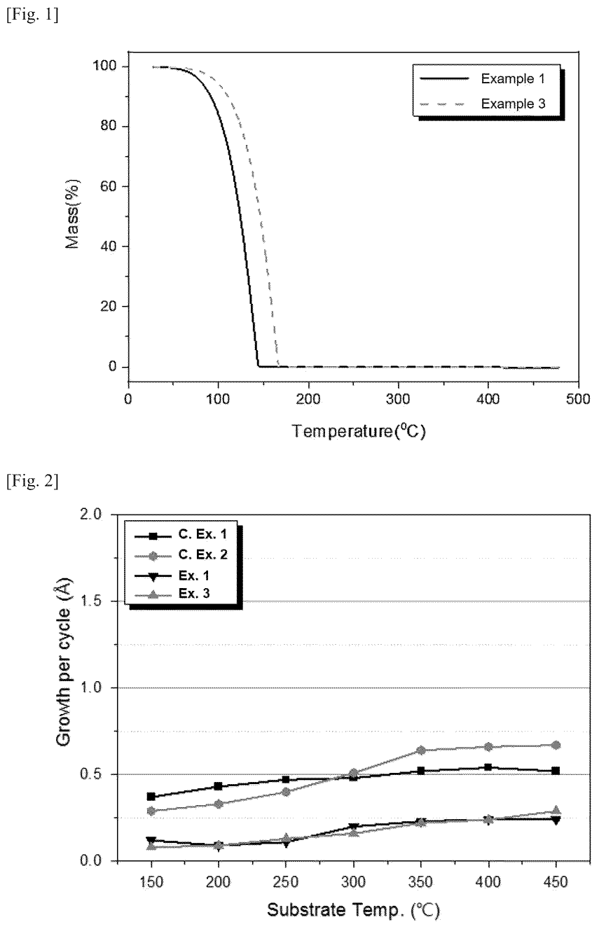

Thermogravimetric analysis (TGA) was carried out for the silicon precursor compounds prepared in Examples 1 and 3 among the above examples, and the results are shown in FIG. 1.

As can be seen from FIG. 1, the silicon precursor compounds prepared in Examples 1 and 3 are preferable for the purpose of forming a silicon-containing film by a chemical vapor deposition method or an atomic layer deposition method since they vaporize without leaving a residue.

### <Test Example 2> Analysis of the Deposition Characteristics of a Composition for Forming a Silicon-Containing Film Comprising a Silicon Precursor Compound at Low and High Temperatures

A composition for forming a silicon-containing film comprising each of the silicon precursor compounds of the Examples and Comparative Examples and ozone (O₃) as a reaction gas were used to form a silicon-containing film by ALD.

First, a silicon substrate was immersed in Piranha solution in which sulfuric acid (H₂SO₄) and hydrogen peroxide (H₂O₂) had been mixed at a ratio of 4:1 for about 10 minutes and then taken out. It was then immersed in a dilute aqueous HF solution for 2 minutes to form a fresh surface. A silicon-containing oxide film was then formed on the silicon substrate by ALD.

A composition for forming a silicon-containing film comprising a silicon precursor compound was placed in a container made of stainless steel. An argon (Ar) carrier gas flowed at a flow rate of about 200 sccm to supply the composition for depositing a film in a gaseous state to the reaction chamber at room temperature while the process pressure of the reactor was set to 4 Torr.

In order to confirm the deposition characteristics of each silicon-containing oxide film, the gas supply cycle was repeated 100 times, in which the composition for forming a film in a gases state was supplied for about 3 seconds; argon (Ar) gas was supplied for about 10 seconds to remove the composition for forming a film (gas) remaining in the reactor; ozone (O₃) was supplied as a reaction gas for about 5 seconds; and argon (Ar) gas was supplied for about 10 seconds to remove ozone (O₃) remaining in the reactor.

The thickness of each oxide film formed using the composition for forming a silicon-containing film prepared by the methods of the Examples and Comparative Examples was measured using an ellipsometer (M-2000, J. A. Woollam).

Thereafter, the measured thickness was divided by the number of gas supply cycles (100 times) to calculate the growth per cycle (GPC) of ALD gas supply.

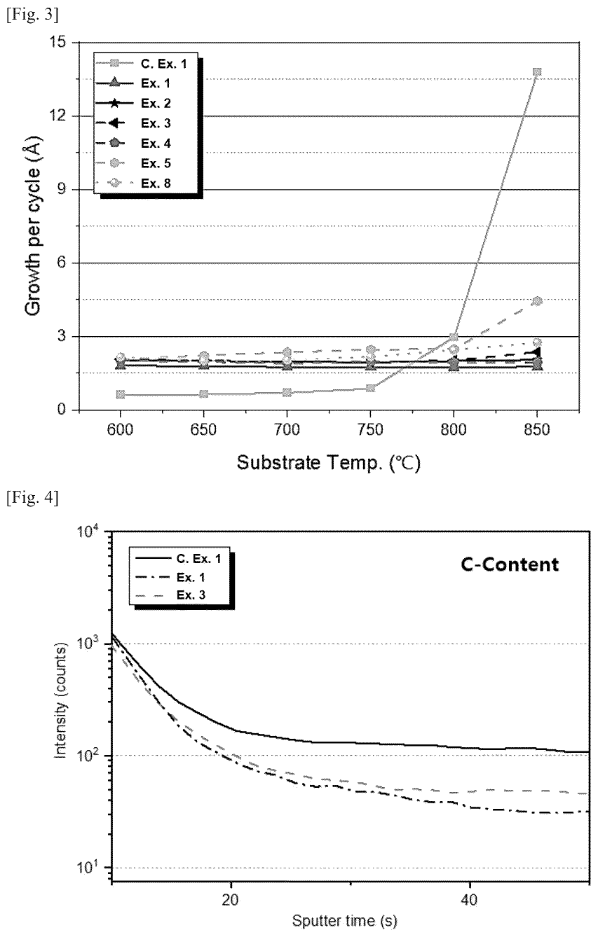

Specifically, the growth per cycle (GPC) of ALD gas supply with respect to a temperature (process temperature) of 150° C. to 450° C. and 600° C. to 850° C. was measured, respectively. The results are shown in FIGS. 2 and 3 and Tables 1 and 2.

TABLE 1

| Deposition | Growth per cycle (GPC) of ALD gas supply (Å/cycle) | | | |
|---|---|---|---|---|
| temp. (° C.) | Ex. 1 | Ex. 3 | C. Ex. 1 | C. Ex. 2 |
| 150 | 0.12 | 0.08 | 0.37 | 0.29 |
| 200 | 0.09 | 0.09 | 0.43 | 0.33 |
| 250 | 0.11 | 0.13 | 0.47 | 0.40 |
| 300 | 0.20 | 0.16 | 0.48 | 0.51 |
| 350 | 0.23 | 0.22 | 0.52 | 0.64 |
| 400 | 0.24 | 0.24 | 0.54 | 0.66 |
| 450 | 0.24 | 0.29 | 0.52 | 0.67 |

TABLE 2

| Deposition | Growth per cycle (GPC) of ALD gas supply (Å/cycle) | | | | | | |
|---|---|---|---|---|---|---|---|
| temp. (° C.) | Ex. 1 | Ex. 2 | Ex. 3 | Ex. 4 | Ex. 5 | Ex. 8 | C. Ex. 1 |
| 600 | 1.81 | 2.04 | 2.08 | 2.01 | 2.10 | 2.17 | 0.62 |
| 650 | 1.79 | 2.01 | 2.02 | 1.98 | 2.23 | 2.01 | 0.64 |
| 700 | 1.75 | 1.98 | 1.94 | 1.90 | 2.36 | 2.04 | 0.71 |
| 750 | 1.75 | 1.95 | 1.96 | 1.99 | 2.47 | 2.18 | 0.88 |
| 800 | 1.74 | 2.00 | 2.03 | 1.94 | 2.49 | 2.45 | 2.97 |
| 850 | 1.77 | 2.05 | 2.37 | 1.93 | 4.45 | 2.76 | 13.78 |

As can be seen from Table 1 and FIG. 2, when ALD deposition was carried out at a low temperature of 150 to 450° C. using the composition for forming a silicon-containing film comprising each of the silicon compounds of Examples 1 and 3, the growth per cycle (GPC) of ALD gas supply was significantly lower than that of Comparative Examples 1 and 2. In particular, the growth per cycle (GPC) of ALD gas supply using the composition for forming a silicon-containing film of the present invention at about 300° C., which is the temperature for forming a capacitor dielectric film of DRAM, was very low at about 0.16 to 0.20 Å/cycle.

In contrast, when the composition for forming a silicon-containing film comprising the silicon compound of Comparative Example 1 was used, the growth per cycle (GPC) of ALD gas supply was 0.48 Å/cycle. When the composition for forming a silicon-containing film comprising the silicon compound of Comparative Example 2 was used, the growth per cycle (GPC) of ALD gas supply was 0.51 Å/cycle. They increased by 2 times or more as compared with the case where the composition for forming a silicone-containing film of the Examples of the present invention was used.

In addition, when the composition for forming a silicon-containing film comprising the silicon compound of Comparative Example 1 or 2 was used, the SiO₂ film can only be adjusted in a unit of 0.5 Å/cycle, such as 0.5, 1.0, and 1.5 Å/cycle. In contrast, when the composition for forming a silicon-containing film of the present invention is used, the film thickness can be adjusted in a unit of 0.2 Å/cycle or less, so that the SiO₂ film thickness can be adjusted precisely twice or more.

Meanwhile, as can be seen from Table 2 and FIG. 3, when ALD was carried out at a high temperature of 600° C. or higher, in the case where the composition for forming a silicone-containing film comprising the silicone compound of each of Examples 1, 2, 3, 4, 5, and 8 was used, a constant GPC was achieved at a relatively high temperature of 600° C. to 850° C., as compared with the case where the composition for forming a silicone-containing film comprising the silicone compound of Comparative Example 1 was used.

Specifically, when the composition for forming a silicon-containing film comprising the silicon compound of Comparative Example 1 was used, the growth per cycle (GPC) of ALD gas supply increased from about 700° C. In contrast, when the composition for forming a silicon-containing film comprising the silicon compound of each of Examples 1, 2, 3, and 4 was used, the growth per cycle (GPC) of ALD gas supply was constant even at a high temperature of 850° C. It was confirmed from the above that the composition for forming a silicone-containing film comprising the silicone compound of the Examples of the present invention achieves a constant GPC at a high temperature of 600° C. to 850° C. and shows self-limiting film growth characteristics; thus, it is a precursor suitable for an ALD process at high temperatures.

### <Test Example 3> Analysis of the Physical Properties of a Silicon-Containing Oxide Film Deposited at High Temperatures

The composition for forming a silicon-containing film comprising the silicon compound of each of Examples 1 and 3 and Comparative Example 1 was used to form a SiO₂ film having the same thickness on a flat wafer at 750° C. as the ALD gas supply cycle was adjusted. Its physical and chemical properties were analyzed.

Specifically, the shrinkage and wet etch rate (WER, Å/s) of the SiO₂ film were measured. The thickness of the SiO₂ film was measured with an ellipsometer (M-2000, J. A. Woollam).

The thickness of the silicon-containing film (SiO₂ film) having an initial thickness of about 100 Å formed on a flat wafer at 750° C., as shown in Table 3, by adjusting the ALD gas supply cycle was compared with the thickness of the silicon-containing film (SiO₂ film) upon annealing in an argon (Ar) atmosphere at 750° C. for 60 minutes to calculate the shrinkage according to Equation 1.

$$Shrinkage ( {S}_{750} , \% ) = \frac{A - B}{A} \times 100 \qquad [ Equation 1 ]$$

In Equation 1, A is the initial thickness (Å) of a silicon-containing film formed by ALD at 750° C., and B is the thickness (Å) of the silicon-containing film formed by ALD at 750° C. after it is left at 750° C. in an argon (Ar) atmosphere for 60 minutes.

The results are shown in Table 3.

TABLE 3

| | Ex. 1 | Ex. 3 | C. Ex. 1 |
|---|---|---|---|
| Compound | Formula 1-1 | Formula 1-3 | 3DMAS |
| Initial thickness (Å) of a SiO₂ film | 101.9 | 102.3 | 101.8 |
| formed by ALD at 750° C. (A) | | | |
| Thickness (Å) of the SiO₂ film | 98.69 | 100.08 | 95.28 |
| formed by ALD at 750° C. after it | | | |
| was left at 750° C. in an argon | | | |
| (Ar) atmosphere for 60 minutes (B) | | | |
| Shrinkage (S₇₅₀, %) | 3.15 | 2.17 | 6.40 |

As can be seen from Table 3 above, the shrinkage of the silicon-containing oxide film (SiO₂ film) deposited using the composition for forming a silicon-containing film of each of Examples 1 and 3 was 3.15% and 2.17%, respectively. In contrast, the shrinkage of the silicon-containing oxide film deposited using the composition for forming a silicon-containing film of Comparative Example 1 was 6.40%. As such, the silicon-containing oxide film deposited using the composition for forming a silicon-containing film of each of Examples 1 and 3 had a smaller shrinkage than that of the silicon-containing oxide film deposited using the composition for forming a silicon-containing film of Comparative Example 1.

Meanwhile, the silicon-containing film (SiO₂ film) having an initial thickness of about 500 Å formed on a flat wafer at 750° C., as shown in Table 4 below, by adjusting the ALD gas supply cycle was etched in a 1% dilute HF solution for 30 seconds. The thickness change was measured to calculate the wet etch rate (WER, Å/s) according to Equation 2.

$$Wet etch rate ( Å / s ) = etch thickness change ( Δ E , Å ) / 30 s \qquad [ Equation 2 ]$$

The etch thickness change (ΔE) may be represented by the following Equation 2-1:

$$Etch thickness change ( Δ E , Å ) = {E}_{A} - {E}_{B} \qquad [ Equation 2 - 1 ]$$

In Equation 2-1, E_{A} is the initial thickness (Å) of a silicon-containing film formed by ALD at 750° C., and E_{B} is the thickness (Å) of the silicon-containing film formed by ALD at 750° C. after it is etched in a 1% dilute HF solution for 30 seconds.

In Equation 2, “s” means seconds.

The results are shown in Table 4.

TABLE 4

| | Ex. 1 | Ex. 3 | C. Ex. 1 |
|---|---|---|---|
| Compound | Formula 1-1 | Formula 1-3 | 3DMAS |
| Initial thickness (Å) of a SiO₂ film | 499.6 | 501.3 | 503.4 |
| formed by ALD at 750° C. (E_{A}) | | | |
| Thickness (Å) of the SiO₂ film | 436.6 | 457.8 | 416.4 |
| formed by ALD at 750° C. after it | | | |
| was etched in a 1% dilute HF | | | |
| solution for 30 seconds (E_{B}) | | | |
| Wet etch rate (E_{A} − E_{B})/30 s (Å/s) | 2.10 | 1.45 | 2.90 |

As can be seen from Table 4 above, the wet etch rate of the silicon-containing oxide film (SiO₂ film) deposited using the composition for forming a silicon-containing film of each of Examples 1 and 3 was 2.10 Å/s and 1.45 Å/s, respectively. In contrast, the wet etch rate of the silicon-containing oxide film deposited using the composition for forming a silicon-containing film of Comparative Example 1 was 2.90 Å/s. The silicon-containing oxide film deposited using the composition for forming a silicon-containing film of each of Examples 1 and 3 was significantly decreased.

Meanwhile, in order to confirm impurities in the silicon-containing oxide layer, secondary ion mass spectrometry (SIMS) was carried out for the silicon-containing oxide film.

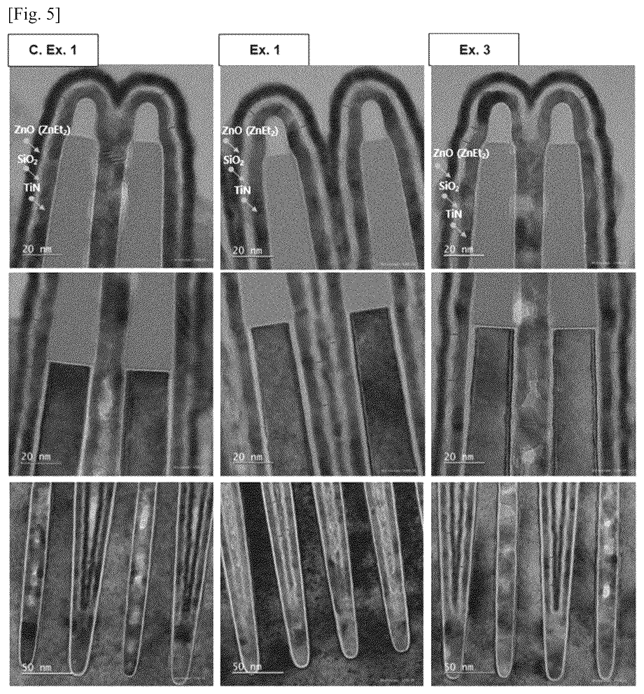

FIG. 4 is a graph showing the results of secondary ion mass spectrometry (SIMS) of a silicon-containing oxide film deposited at a temperature of 750° C. using each of the compositions for forming a silicon-containing film of Examples 1 and 3 and Comparative Example 1 of the present invention.

In order to confirm impurities in the silicon-containing oxide layer deposited using the composition for forming a silicon-containing film of each of Comparative Example 1 and Examples 1 and 3, the silicon-containing oxide film deposited to a thickness of about 100 Å was analyzed for a carbon (C) content by SIMS.

As a result, the carbon content was reduced by about 63% in Example 1 and by about 55% in Example 3 as compared with Comparative Example 1, indicating that a pure silicon-containing oxide film with less than 100 counts of carbon content was formed.

FIG. 5 is a transmission electron microscope (TEM) image of the silicon-containing oxide film formed on a wafer with a deep pattern at 750° C. by ALD using each of the composition for depositing a silicon-containing film of Examples 1 and 3 and Comparative Example 1 of the present invention and ozone. Table 5 shows the thickness of the silicon-containing oxide film measured in the part shown in FIG. 5.

TABLE 5

| | Ex. 1 | Ex. 3 | C. Ex. 1 |
|---|---|---|---|
| Compound | Formula 1-1 | Formula 1-3 | 3DMAS |
| Thickness (Å) measured at the top | 28.8 | 36.8 | 28.6 |
| of the groove | 29.9 | 36.7 | 28.4 |
| | 29.2 | 35.4 | 30.6 |
| Average thickness (Å) measured at | 29.3 | 36.3 | 29.2 |
| the top of the groove (A) | | | |
| Thickness (Å) measured at the | 28.1 | 35.4 | 22.3 |
| bottom of the groove | 28.0 | 35.7 | 22.2 |
| | 28.1 | 34.2 | 23.9 |
| Average thickness (Å) measured at | 28.1 | 35.1 | 22.8 |
| the bottom of the groove (B) | | | |
| Step coverage (%) (B/A × 100 | 95.9% | 96.7% | 78.1% |
| (%)) | | | |

As can be seen from Table 5, when the composition for forming a silicon-containing film of each of Examples 1 and 3 and Comparative Example 1 was deposited on a substrate having a step and then analyzed using TEM, the step coverage of the silicon-containing oxide film deposited using the composition for forming a silicon-containing film of each of Examples 1 and 3 was 95.9% and 96.7%, respectively. In contrast, the step coverage of the silicon-containing oxide film deposited using the composition for forming a silicon-containing film of Comparative Example 1 was 78.1%. The silicon-containing oxide film deposited using the composition for forming a silicon-containing film of each of Examples 1 and 3 had a remarkably excellent step coverage as compared with the silicon-containing oxide film deposited using the composition for forming a silicon-containing film of Comparative Example 1.

In sum, according to the method for forming a silicon-containing film using the composition for forming a silicon-containing film comprising the silicon precursor compound according to an embodiment of the present invention, it was possible to readily deposit a silicon-containing film by ALD, to precisely control the film thickness and composition, and to form a uniform film with excellent coverage even on a substrate having a complex shape.

In particular, according to the method for forming a silicon-containing film using the composition for forming a silicon-containing film comprising the silicon precursor compound according to the present invention, it is possible to obtain a film of a desired thickness at a high temperature of 600° C. to 850° C., as well as a low temperature of 150° C. to 450° C., during deposition. The silicon-containing oxide film thus obtained had significantly improved physical properties, such as step coverage, shrinkage, and wet etch rate, as compared with the silicon-containing oxide film using the composition for forming a silicon-containing film comprising the silicon precursor compound of Comparative Example 1.

1. A composition for forming a silicon-containing film, which comprises a silicon precursor compound represented by the following Formula 1: 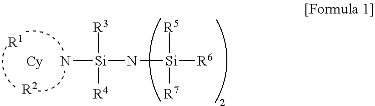
in Formula 1,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O)), nitrogen (N), and carbon (C), and
R³ to R⁷ are each independently selected from the group consisting of hydrogen, a linear or branched C₁-C₄ alkyl group, and a linear or branched C₂-C₆ alkenyl group, provided that at least one of R³ and R⁴ is not hydrogen; and that at least one of R⁵ to R⁷ is not hydrogen.

2. The composition for forming a silicon-containing film of claim 1, wherein the silicon precursor compound comprises at least one selected from the group consisting of compounds represented by the following Formulae:

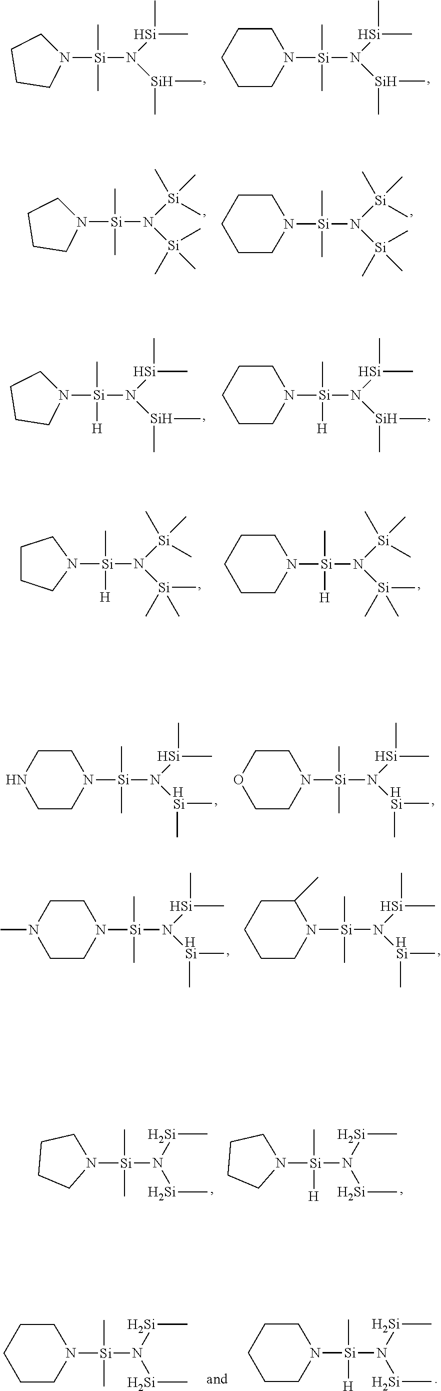

3. The composition for forming a silicon-containing film of claim 1, wherein when a SiO₂ film is formed by an atomic layer deposition (ALD) method using the composition for forming a silicon-containing film, the growth per cycle (GPC) of ALD gas supply is 0.08 to 4.5 Å/cycle in a temperature range of 150° C. to 850° C.

4. The composition for forming a silicon-containing film of claim 3, wherein when a SiO₂ film is formed by an atomic layer deposition (ALD) method using the composition for forming a silicon-containing film,
the growth per cycle of ALD gas supply is 0.08 to 0.35 Å/cycle in a temperature range of 150° C. to 400° C., or
the growth per cycle of ALD gas supply is 0.20 to 2.5 Å/cycle in a temperature range of higher than 400° C. to lower than 600° C., or
the growth per cycle of ALD gas supply is 1.5 to 4.5 Å/cycle in a temperature range of 600° C. to 850° C.

5. A method for forming a silicon-containing film, which comprises depositing a silicon-containing film using a composition for forming a silicon-containing film comprising a silicon precursor compound represented by Formula 1: 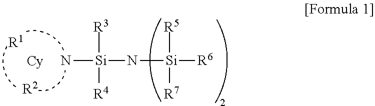
in Formula 1,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O)), nitrogen (N), and carbon (C), and
R³ to R⁷ are each independently selected from the group consisting of hydrogen, a linear or branched C₁-C₄ alkyl group, and a linear or branched C₂-C₆ alkenyl group, provided that at least one of R³ and R⁴ is not hydrogen; and that at least one of R⁵ to R⁷ is not hydrogen.

6. The method for forming a silicon-containing film of claim 5, wherein the silicon precursor compound comprises at least one selected from the group consisting of compounds represented by the following Formulae:

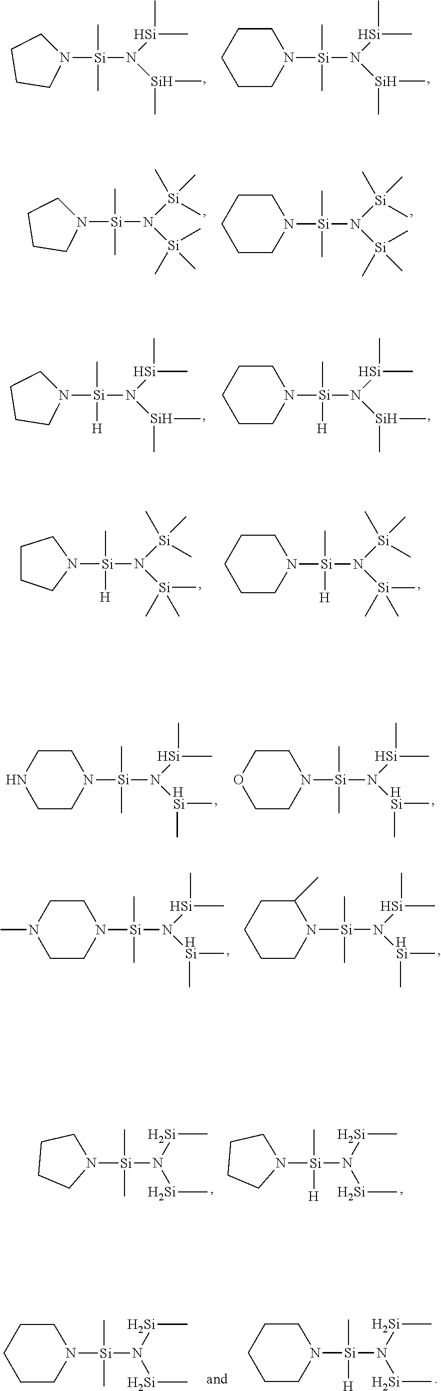

7. The method for forming a silicon-containing film of claim 5, wherein the silicon-containing film is formed at a temperature of 150° C. to 850° C. by chemical vapor deposition (CVD) or atomic layer deposition (ALD).

8. The method for forming a silicon-containing film of claim 5, wherein the method for forming a silicon-containing film comprises supplying the silicon precursor compound into a reaction chamber using at least one method selected from the group consisting of a bubbling method; a liquid delivery system (LDS) method; a vapor flow control (VFC) method; and a bypass method.

9. The method for forming a silicon-containing film of claim 8, wherein the supplying of the silicon precursor compound into a reaction chamber is carried out using a transport gas or a diluent gas in a temperature range of room temperature to 150° C. and 0.1 to 10 Torr.

10. The method for forming a silicon-containing film of claim 5, wherein, during the deposition, thermal energy or plasma is used, or a bias is applied onto the substrate.

11. The method for forming a silicon-containing film of claim 5, wherein the silicon-containing film comprises a silicon-containing oxide film or a silicon-containing composite metal oxide film, and
at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O₂), hydrogen peroxide (H₂O₂), and ozone (O₃) is used during the deposition.

12. The method for forming a silicon-containing film of claim 5, wherein the silicon-containing film comprises a silicon-containing nitride film or a silicon-containing composite metal nitride film, and
at least one selected from the group consisting of ammonia (NH₃), ammonia plasma (HN₃ plasma), hydrazine (N₂H₄), and nitrogen plasma (N₂ plasma) is used during the deposition.

13. The method for forming a silicon-containing film of claim 5, wherein the silicon-containing film is formed in a thickness range of 1 nm to 500 nm.

14. The method for forming a silicon-containing film of claim 5, wherein the silicon-containing film is formed on a substrate having at least one irregularity having an aspect ratio of 1 or more and a width of 1 μm or less.

15. A silicon precursor compound represented by the following Formula 1: 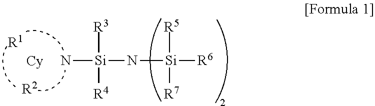
in Formula 1,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O), nitrogen (N), and carbon (C), and
R³ to R⁷ are each independently selected from the group consisting of hydrogen, a linear or branched C₁-C₄ alkyl group, and a linear or branched C₂-C₆ alkenyl group, provided that at least one of R³ and R⁴ is not hydrogen; and that at least one of R⁵ to R⁷ is not hydrogen.

16. The silicon precursor compound of claim 15, represented by any one of the following Formulae:

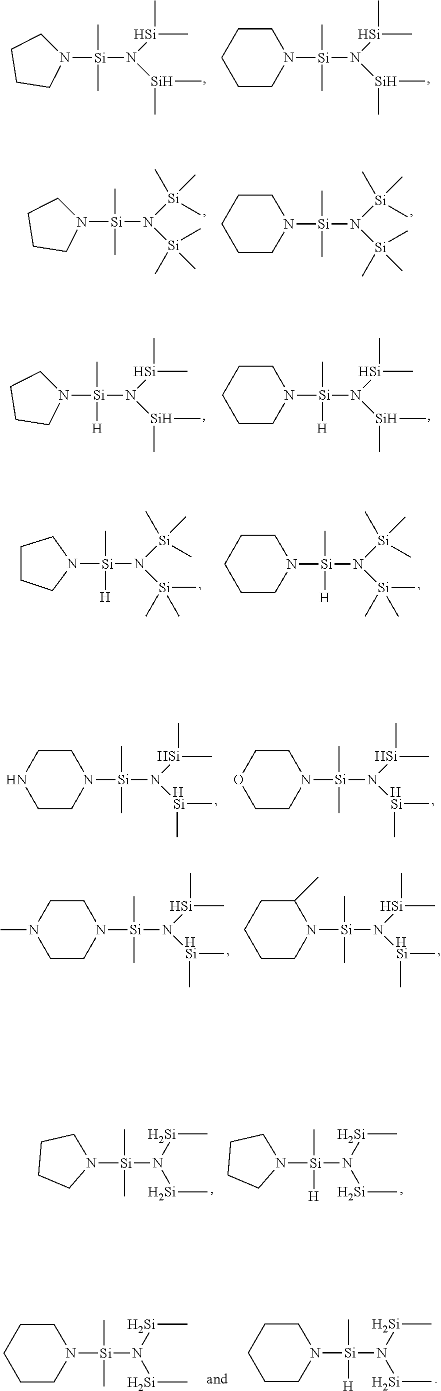

17. A method for preparing a silicon precursor compound represented by the following Formula 1, which comprises subjecting an alkyldisilazane metal salt represented by the following Formula A to a halide-amine substitution reaction with triethylamine, a dihalide silicon precursor compound represented by the following Formula B, and a heterocyclic amine or a heterocyclic amine metal salt represented by the following Formula C: 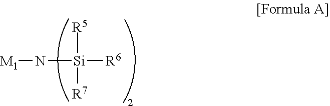
in Formula A,
M₁ is an alkali metal and Li or Na, and
R⁵ to R⁷ are each independently selected from the group consisting of hydrogen, a linear or branched C₁-C₄ alkyl group, and a linear or branched C₂-C₆ alkenyl group, provided that at least one of R⁵ to R⁷ is not hydrogen, 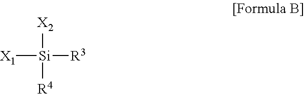
in Formula B,
X₁ and X₂ are each independently a halogen element and Cl, Br, or I, and
R³ and R⁴ are each independently selected from the group consisting of hydrogen, a linear or branched C₁-C₄ alkyl group, and a linear or branched C₂-C₆ alkenyl group, provided that at least one of R³ and R⁴ is not hydrogen, 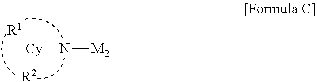
in Formula C,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O), nitrogen (N), and carbon (C), and
M₂ is selected from the group consisting of hydrogen, Li, and Na, and 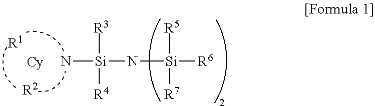
in Formula 1,
Cy is a ring in which N, R¹, and R² are directly or indirectly linked to each other and refers to a substituted or unsubstituted C₄-C₈ heterocyclic ring,
R¹ and R² are each independently selected from the group consisting of oxygen (O), nitrogen (N), and carbon (C), and
R³ to R⁷ are each independently selected from the group consisting of hydrogen, a linear or branched C₁-C₄ alkyl group, and a linear or branched C₂-C₆ alkenyl group, provided that at least one of R³ and R⁴ is not hydrogen; and that at least one of R⁵ to R⁷ is not hydrogen.
